(19) United States
(12) Patent Application Publication
(10) Pub. No.: US 2019/0393127 A1
(43) Pub. Date: Dec. 26, 2019

(54) SEMICONDUCTOR PACKAGE WITH INTEGRATED HEAT SINK

(71) Applicant: SEMICONDUCTOR COMPONENTS INDUSTRIES, LLC, Phoenix, AZ (US)

(72) Inventor: Darrell D. TRUHITTE, Phoenix, AZ (US)

(73) Assignee: SEMICONDUCTOR COMPONENTS INDUSTRIES, LLC, Phoenix, AZ (US)

(21) Appl. No.: 16/013,397

(22) Filed: Jun. 20, 2018

(51) Int. Cl. H01L 23/367; H01L 23/00; H01L 23/31

(52) U.S. Cl. CPC H01L 23/3677; H01L 23/3672; H01L 2224/73253; H01L 23/3185; H01L 24/73

(57) ABSTRACT

Implementations of semiconductor packages may include: a heat sink including a plurality of projections extending from a first side of the heat sink and a die having a first side and a second side. The first side of the die may be coupled directly to a second side of the heat sink through a thermally conductive and electrically isolating material. The package may also include one or more interconnects including a solderable metal. The one or more interconnects may be coupled to the second side of the die. The package may also include a molding compound around the die and the one or more interconnects. The molding compound may be directly coupled to the second side of the heat sink.

### BACKGROUND

### 1. Technical Field

Aspects of this document relate generally to semiconductor packages, such as semiconductor packages having heat sinks.

### 2. Background

Heat sinks are often used to transfer heat from internal components of a semiconductor package to ambient air or another cooling fluid. A heat sink operates to transfer heat via conductive and also convective mechanisms through the material selected for the heat sink and the way the cooling fluid or air contacts the material of the heat sink.

### SUMMARY

Implementations of semiconductor packages may include: a heat sink including a plurality of projections extending from a first side of the heat sink and a die having a first side and a second side. The first side of the die may be coupled directly to a second side of the heat sink through a thermally conductive and electrically isolating material. The package may also include one or more interconnects including a solderable metal. The one or more interconnects may be coupled to the second side of the die. The package may also include a molding compound around the die and the one or more interconnects. The molding compound may be directly coupled to the second side of the heat sink.

Implementations of semiconductor packages may include one, all, or any of the following:

The heat sink may be derived from a lead frame.

The heat sink may include a thickness of between 4 mils to at least 50 mils.

The thermally conductive and electrically isolating material may include solder, epoxy, die attach film, or any combination thereof.

The one or more interconnects may include copper pillars, solder, or plated pads.

The plurality of projections may include squares, concentric circles, lines, or waved lines.

Implementations of semiconductor packages may include: a heat sink derived from a lead frame. The heat sink may include a first side and a second side and a plurality of projections may extend from the first side of the lead frame. The package may include a die having a first side and a second side. The first side of the die may be coupled directly to a second side of the heat sink through a thermally conductive and electrically isolating material. The package may also include one or more interconnects coupled to the second side of the die. The one or more interconnects may include a solderable metal on a second side of the interconnect opposite the die. The package may also include a molding compound coupled around the die and the one of more interconnects, wherein the molding compound is directly coupled to the second side of the heat sink.

Implementations of semiconductor packages may include one, all, or any of the following:

The heat sink may include a thickness of between 4 mils to at least 50 mils.

The thermally conductive and electrically isolating material may include solder, epoxy, die attach film, or any combination thereof.

The one or more interconnects may include one of copper pillars, solder, or plated pads.

The plurality of projections may include one of squares, concentric circles, lines, and waved lines.

Implementations of a method of manufacturing a semiconductor package may include: providing a lead frame. The lead frame may include a plurality of heat sinks and each heat sink may include a first side and a second side. A plurality of projections may extend from the first side of each heat sink. The method may include coupling a first side of a plurality of die to the second side of each heat sink. A die of the plurality of die may include a plurality of interconnects extending from a second side of the die. The method may include encapsulating the plurality of die and the plurality of interconnects through an encapsulation material. The method may include grinding the encapsulation material and exposing a surface of the plurality of interconnects. The method may include singulating the lead frame on a plurality of saw streets to form a plurality of semiconductor packages.

Implementations of a method of manufacturing semiconductor packages may include one, all, or any of the following:

The method may further include electroplating the surface of the plurality of interconnects.

The method may further include electrically and mechanically coupling one of the plurality of semiconductor packages to a circuit board through the plurality of interconnects.

Coupling a first side of a die to the second side of the metal substrate may include a thermally conductive and electrically isolating material.

The thermally conductive and electrically isolating material may include solder, epoxy, die attach film, or any combination thereof.

The one or more interconnects may include copper pillars.

The plurality of projections may include squares, concentric circles, lines, or waved lines.

Singulating may be performed through a saw, a laser, a high-pressure water jet, or a combination thereof.

The method may further include coupling a first side of a second die to the second side of the heat sink. The second die may include a second plurality of interconnects extending from a second side of the second die.

The foregoing and other aspects, features, and advantages will be apparent to those artisans of ordinary skill in the art from the DESCRIPTION and DRAWINGS, and from the CLAIMS.

### BRIEF DESCRIPTION OF THE DRAWINGS

Implementations will hereinafter be described in conjunction with the appended drawings, where like designations denote like elements, and:

FIG. 1 is a cross sectional view of an implementation of a semiconductor package coupled with a printed circuit board;

FIG. 2 is a top perspective view of an implementation of a semiconductor package;

FIG. 3 is a bottom perspective view of an implementation of a semiconductor package;

FIG. 4 is a top view an implementation of a heat sink having a plurality of projections;

FIG. 5 is a side view an implementation of a heat sink having a plurality of projections;

FIG. 6 is a side view an implementation of a die coupled to a heat sink, the die having one or more interconnects coupled thereto;

FIG. 7 is a side view of encapsulation material coupled around an implementation of a die coupled to a heat sink;

FIG. 8 is a side view of encapsulation material coupled around an implementation of a die coupled to a heat sink after grinding of the encapsulation material;

FIG. 9 is a side view of an implementation of a semiconductor coupled with a printed circuit board through copper pillars;

FIG. 10 is a bottom view of an implementation of a semiconductor package illustrating a pattern of interconnects;

FIG. 11 is a bottom view of an implementation of a semiconductor package illustrating a pattern of interconnects;

FIG. 12 is a bottom view of an implementation of a semiconductor package illustrating a pattern of interconnects;

FIG. 13 is a bottom view of an implementation of a semiconductor package illustrating a pattern of interconnects;

FIG. 14 is a bottom view of an implementation of a semiconductor package illustrating a pattern of interconnects;

FIG. 15 is a bottom view of an implementation of a semiconductor package illustrating a pattern of interconnects;

FIG. 16 is a bottom view of an implementation of a semiconductor package illustrating a pattern of interconnects;

FIG. 17 is a bottom view of an implementation of a semiconductor package illustrating a pattern of interconnects;

FIG. 18 is a top view of an implementation of a heat sink having square projections;

FIG. 19 is a top view of an implementation of a heat sink having concentric circle projections;

FIG. 20 is a top view of an implementation of a heat sink having line projections;

FIG. 21 is a top view of an implementation of a heat sink having waved line projections;

FIG. 22 is a bottom view of an implementation of a semiconductor package having three die in a lateral position;

FIG. 23 is a side view of the implementation of the semiconductor package from FIG. 22;

FIG. 24 is a bottom view of an implementation of a semiconductor package having two die stacked and one in a lateral position;

FIG. 25 is a side view of an implementation of a semiconductor package having two die stacked and one in a lateral position;

FIG. 26 is a top view of an implementation of a lead frame having a plurality of heat sinks; and

FIG. 27 is a side view of the implementation of the leadframe illustrated in FIG. 26.

### DESCRIPTION

This disclosure, its aspects and implementations, are not limited to the specific components, assembly procedures or method elements disclosed herein. Many additional components, assembly procedures and/or method elements known in the art consistent with the intended semiconductor packages will become apparent for use with particular implementations from this disclosure. Accordingly, for example, although particular implementations are disclosed, such implementations and implementing components may comprise any shape, size, style, type, model, version, measurement, concentration, material, quantity, method element, step, and/or the like as is known in the art for such semiconductor packages, and implementing components and methods, consistent with the intended operation and methods.

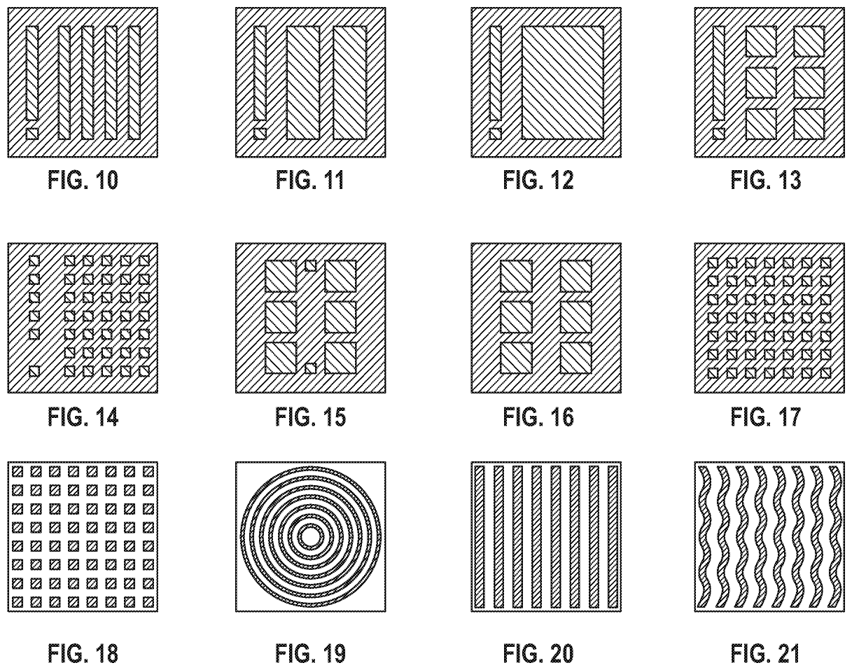

Referring to FIG. 1, an implementation of a semiconductor package 2 is illustrated. The semiconductor package includes a heat sink 4 having a plurality of projections extending from the first side of the heat sink 4. In various implementations, the projections may be squares as shown in FIG. 18, concentric circles as illustrated in FIG. 19, lines as illustrated in FIG. 20, and waved lines as illustrated in FIG. 21. In some implementations, the plurality of projections may be any shape that may maximize the surface of the heat sink such as, by non-limiting example, circles, ellipses, cones, and any other shape capable of producing increased surface area. Referring again to FIG. 1, the semiconductor package includes a die 6 coupled directly to the heat sink 4. More specifically a first side of the die 6 is coupled to the second side of the heat sink 4 through a thermally conductive and electrically isolating material. In various implementations, a material that is electrically conductive may be used to couple the first side of the die directly to the second side of the heat sink. In various implementations, the thermally conductive and electrically isolating material may be solder, epoxy, die attach film, or any combination thereof. In this implementation, the die 6 includes interconnects 8 coupled to the second side of the die 6. The interconnects include a solderable metal. In various implementations, there may be one or more interconnects, and/or the interconnects may be formed of the same solderable metal or different solderable metals. In some implementations, the interconnects may be formed in any of the variety of shapes and sizes, including any illustrated in FIGS. 10-17 and any combination thereof.

Referring to FIG. 1, the package also includes a molding compound 10 coupled around the die and the interconnects 8. As illustrated, the molding compound 10 is coupled directly to the second side of the heat sink 4. In various implementations, the heat sink 4 may be created using a lead frame. In various implementations, the lead frame may be copper. By non-limiting example, the heat sink may have a thickness between about 4 mils to at least about 50 mils. In various implementations, the heat sink may include thermally conductive non-metals such as, by non-limiting example, aluminum oxide, thermally conductive epoxies, ceramics, and other non-metallic materials with thermal conductivities similar to metals. The semiconductor package is illustrated in FIG. 1 as mechanically and electrically coupled to a printed circuit board through the interconnects. In various implementations, the interconnects may be copper pillars, solder, or electro- or electroless-plated pads.

The packages as described herein may have a high die to circuit board ratio which may lead to lower values of various electrical parameters such as drain source on-resistance (RDSₒₙ), saturation voltage collector-emitter (VCESAT), and forward voltage (VF). Lower values of these electrical parameters may result in lower overall heat generation, thus lessening the overall heat duty required for the heat sink to handle. In various implementations of the packages, heat may be dissipated through the interconnects and through the top of the package via an air cooled heat sink. In some implementations, heat generated by the packages may flow from the active area of the die to both sides of the die. This structure may be beneficial for die with topside connection such as, by non-limiting example, common drain metal-oxide-semiconductor field-effect transistors (MOSFET), gallium nitride (GaN) devices, eFuse devices, and other similar heat generating devices.

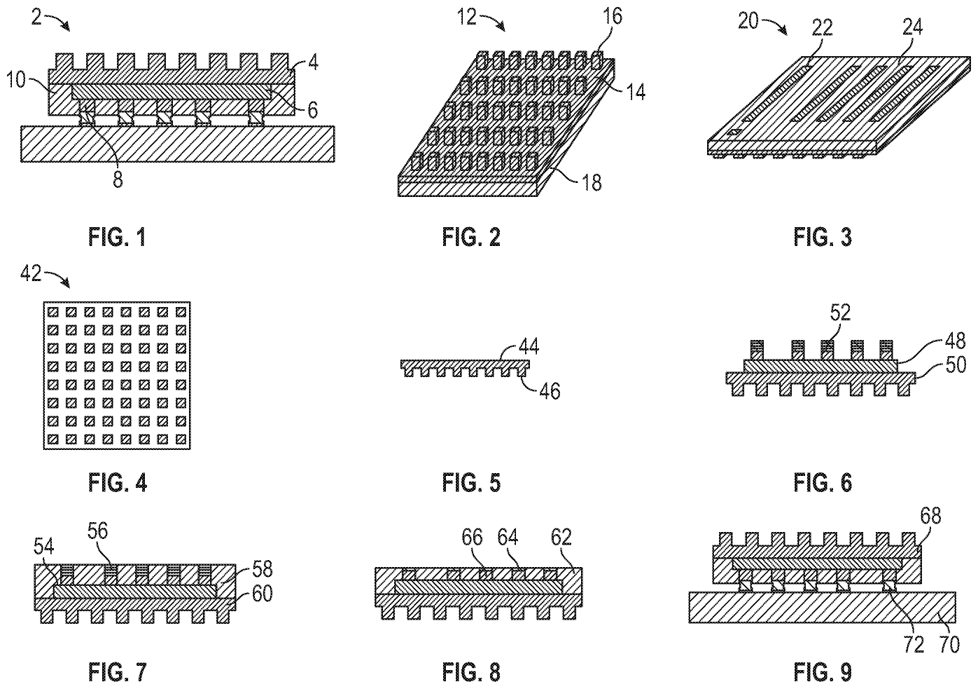

Referring to FIG. 2, a top perspective view of an implementation of a semiconductor package 12 is illustrated. In the top view, the first side of the heat sink 14 is illustrated. In this implementation, the plurality of projections 16 extending from the heat sink are squares (have a square shaped perimeter) when viewed from directly above in a top down view. The molding compound 18 is coupled to the second side of the heat sink 14. By non-limiting example, the molding compound may include epoxy, acrylic, or other suitable electrically insulating materials. Referring to FIG. 3, a bottom perspective view of an implementation of a semiconductor package 20 is illustrated. In this view, the interconnects 22 are illustrated within the molding compound 24. In various implementations, the interconnects may be electroplated for better electrical connectivity.

Referring to FIGS. 4-9, an implementation of a method of manufacturing semiconductor packages is illustrated. To simplify the description, the figures illustrate formation of a single semiconductor package, however, the process may also be carried out using a leadframe on which multiple packages are formed simultaneously using the same processing steps disclosed in this document. An implementation of a full lead frame 26 is illustrated in FIG. 26 to provide an example of what such a lead frame used for simultaneously processing would look like. As can be seen, implementations of lead frames like those in FIG. 26, include a plurality of heat sinks 28. The heat sinks 28 include a plurality of projections 30 that are square (have a square cross section/perimeter when viewed from a top down view). In various implementations, the plurality of projections 30 may have any of the different shapes previously disclosed in this document and the perimeter/cross section of the projections may be any closed shape. In various implementations, saw streets 32 may be etched between each heat sink 28 to aid in singulation. Singulation may be performed through, by non-limiting example, plasma etching, chemical etching, water jet cutting, or any other method of singulation described in this document. Referring to FIG. 27, a side view of an implementation of a lead frame 34 is illustrated. In this view, the plurality of heat sinks 36 are illustrated separated by saw streets 38. Each of the plurality of the heat sinks 36 has a plurality of projections 40 as those illustrated in FIGS. 18-21, as previously described.

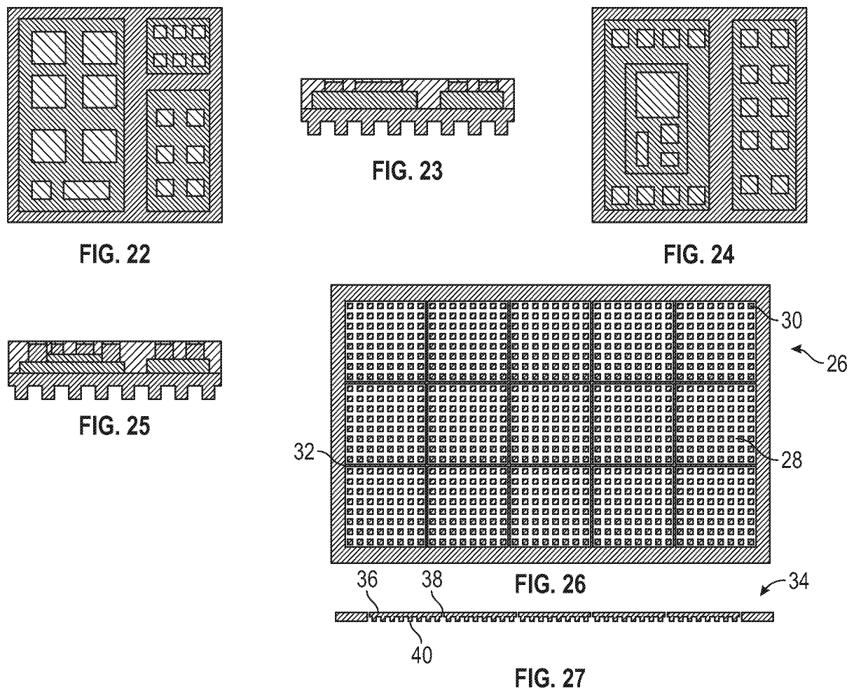

Referring again to FIG. 4, the method for manufacturing semiconductor packages includes providing a lead frame having a plurality of heat sinks 42. Each of the plurality of heat sinks 42 includes a plurality of projections 46 extending from the heat sink 44 on a first side of heat sink as illustrated in FIG. 5. Referring to FIG. 6, the method includes coupling a first side of a plurality of die 48 to the second side of each heat sink 50. Each of the plurality of die 48 includes a plurality of interconnects 52 extending from the second side of the die 48. The die 45 may be coupled to the heat sink 50 through a thermally conductive and electrically isolating material such as, by non-limiting example, solder, epoxy, die attach film, or any combination thereof. In some implementations, electrically conductive materials may be used to couple the die with the heat sink. In various implementations, the method may further include coupling two or more die directly to the heat sink through the thermally conductive and electrically isolating material. Implementations of semiconductor packages including multiple die laterally bonded to the heat sink are illustrated in FIGS. 22 and 23. In still other implementations, the method may further include bonding a second die on top of an existing coupled die. Implementations of semiconductor packages including multiple die in a stacked configuration are illustrated in FIGS. 24 and 25.

Referring to FIG. 7, the method includes encapsulating the die 54 and the plurality of interconnects 56 through an encapsulation material 58. The encapsulation or molding compound 56 may protect the die 54 from water, air, and other contaminants. In various implementations, the encapsulation material may be applied through a compression molding method or a transfer molding method. As illustrated in FIG. 7, after the molding process, the encapsulation material 58 is coupled directly to the second side of the heat sink 60.

Referring to FIG. 8, the method includes grinding the encapsulation material 62 to expose a surface 64 of the plurality of interconnects 66. In various implementations of a method for forming semiconductor packages, the surface of the plurality of interconnects may then be electroplated. With the interconnects exposed, the method includes singulating the lead frame on a plurality of saw streets to form a plurality of semiconductor packages. The packages may be singulated through sawing, high pressure water jet cutting, lasering, etching (including plasma etching or chemical etching), or any other method/process capable of separating the metal and molding compound. Referring to FIG. 9, the method may including electrically and mechanically coupling a semiconductor package 68 to a circuit board 70 through a plurality of interconnects 72.

In various implementations, the methods for forming a semiconductor package with an integral heat sink could be used for larger devices. The method may include attaching a single copper pillar onto a large heatsink and individually encapsulating and planarizing the interconnects using the methods disclosed herein. In other implementations, a bumped die may be used to form/act as the interconnect in a larger device.

In places where the description above refers to particular implementations of semiconductor packages and implementing components, sub-components, methods and sub-methods, it should be readily apparent that a number of modifications may be made without departing from the spirit thereof and that these implementations, implementing components, sub-components, methods and sub-methods may be applied to other semiconductor packages.

1. A semiconductor package comprising:
a heat sink comprising a plurality of projections extending from a first side of the heat sink;
a die comprising a first side and a second side, the first side of the die coupled directly to a second side of the heat sink through a thermally conductive and electrically isolating material;
one or more interconnects comprising a solderable metal, the one or more interconnects coupled to the second side of the die; and
a molding compound coupled around the die and the one or more interconnects;
wherein the one or more interconnects extend through a thickness of the mold compound; and
wherein the molding compound is directly coupled to the second side of the heat sink.

2. The package of claim 1, wherein the heat sink is derived from a lead frame.

3. The package of claim 1, wherein the heat sink comprises a thickness of between 4 mils to at least 50 mils.

4. The package of claim 1, wherein the thermally conductive and electrically isolating material is one of solder, epoxy, die attach film, and any combination thereof.

5. The package of claim 1, wherein the one or more interconnects comprise copper pillars, solder, and plated pads.

6. The package of claim 1, wherein the plurality of projections comprise one of squares, concentric circles, lines, and waved lines.

7. A semiconductor package comprising:
a heat sink derived from a lead frame, the heat sink comprising a first side and a second side wherein a plurality of projections extend from the first side of the lead frame;
a die comprising a first side and a second side, the first side of the die coupled directly to the second side of the heat sink through a thermally conductive and electrically isolating material;
one or more interconnects coupled to the second side of the die, the one or more interconnects comprising a solderable metal on a second side of the interconnect opposite the die; and
a molding compound coupled around the die and the one of more interconnects;
wherein the one or more interconnects extend through a thickness of the mold compound; and
wherein the molding compound is directly coupled to the second side of the heat sink.

8. The package of claim 7, wherein the heat sink comprises a thickness of between 4 mils to at least 50 mils.

9. The package of claim 7, wherein the thermally conductive and electrically isolating material is one of solder, epoxy, die attach film, and any combination thereof.

10. The package of claim 7, wherein the one or more interconnects comprise one of copper pillars, solder, and plated pads.

11. The package of claim 7, wherein the plurality of projections comprise one of squares, concentric circles, lines, and waved lines.

12-20. (canceled)

21. A semiconductor package comprising:
a heat sink comprising a plurality of projections extending from a first side of the heat sink;
a die comprising a first side and a second side, the first side of the die coupled directly to a second side of the heat sink through a thermally conductive and electrically isolating material, wherein the entire second side of the heat sink is coplanar with the entire first side of the die;
one or more interconnects comprising a solderable metal, the one or more interconnects coupled to the second side of the die; and
a molding compound coupled around the die and the one or more interconnects, wherein the molding compound is directly coupled to the second side of the heat sink.

22. The package of claim 21, wherein the heat sink is derived from a lead frame.

23. The package of claim 21, wherein the heat sink comprises a thickness of between 4 mils to at least 50 mils.

24. The package of claim 21, wherein the thermally conductive and electrically isolating material is one of solder, epoxy, die attach film, or any combination thereof.

25. The package of claim 21, wherein the one or more interconnects comprise one of copper pillars, solder, or plated pads.

26. The package of claim 21, wherein the plurality of projections comprise one of squares, concentric circles, lines, or waved lines.
